(19) United States
(12) Patent Application Publication
(10) Pub. No.: US 2026/0101720 A1
(43) Pub. Date: Apr. 9, 2026

(54) SEMICONDUCTOR PACKAGE AND MANUFACTURING METHOD THEREOF

(71) Applicant: Samsung Electronics Co., Ltd., Suwon-si (KR)

(72) Inventors: Kyoung-Min LEE, Suwon-si (KR); Sang-Hoon JUNG, Suwon-si (KR)

(73) Assignee: Samsung Electronics Co., Ltd., Suwon-si (KR)

(21) Appl. No.: 19/274,982

(22) Filed: Jul. 21, 2025

(30) Foreign Application Priority Data
Sep. 25, 2024 (KR) 10-2024-0129780

(51) Int. Cl. H01L 23/00; H01L 21/66; H01L 23/528; H01L 25/04

(52) U.S. Cl. CPC H10P 74/20; H10W 20/43; H10W 90/00; H10W 46/00; H10W 72/9445; H10W 72/967; H10W 90/722; H10W 90/792

(57) ABSTRACT

A semiconductor package includes a first semiconductor chip including: a first substrate, a first wiring layer on a first surface of the first substrate, a plurality of first dummy pads electrically connected to each other by a redistribution layer disposed between the first wiring layer and a first passivation layer, and a plurality of second dummy pads disposed adjacent to the plurality of first dummy pads on the first wiring layer; and a second semiconductor chip including: a second substrate, a second wiring layer on the second substrate and opposite to the first surface of the first substrate, a plurality of third dummy pads having at least a portion that overlaps the plurality of first dummy pads on the second wiring layer, and a plurality of power pads arranged adjacent to the plurality of third dummy pads and configured to provide a test voltage.

### CROSS-REFERENCE TO RELATED APPLICATION

This application is based on and claims priority to Korean Patent Application No. 10-2024-0129780 filed in the Korean Intellectual Property Office on Sep. 25, 2024, the entire contents of which are incorporated herein by reference.

### BACKGROUND OF THE DISCLOSURE

The present disclosure relates to a semiconductor package and a manufacturing method of the semiconductor package.

With a rapid development of electronic industries and user demands, electronic devices are becoming increasingly miniaturized. In order to manufacture miniaturized, high-performance, and large-capacity electronic devices, a method of stacking the semiconductor devices is being proposed. For example, a system-in package in which the stacked heterogeneous chips operate as a single system or a multi-chip package in which a plurality of chips are mounted in a single semiconductor package is presented.

As the semiconductor devices become more integrated, pads that connect the stacked multiple chips are also being miniaturized. As the pad miniaturization increases, the difficulty of the alignment between the stacked chips increases.

### SUMMARY

An embodiment provides a semiconductor package that facilitates the testing alignment between the stacked chips.

According to an aspect of the disclosure, a semiconductor package includes: a first semiconductor chip including: a first substrate, a first wiring layer on a first surface of the first substrate, a plurality of first dummy pads electrically connected to each other by a redistribution layer disposed between the first wiring layer and a first passivation layer, and a plurality of second dummy pads disposed adjacent to the plurality of first dummy pads on the first wiring layer, wherein each second dummy pad of the plurality of second dummy pads is floated; and a second semiconductor chip including: a second substrate, a second wiring layer on the second substrate and opposite to the first surface of the first substrate, a plurality of third dummy pads having at least a portion that overlaps the plurality of first dummy pads on the second wiring layer, and a plurality of power pads arranged adjacent to the plurality of third dummy pads and configured to provide a test voltage.

According to an aspect of the disclosure, a semiconductor package includes a first semiconductor chip including: a first normal region overlapping in a plane a center of a first surface of a first substrate, a plurality of signal power pads, a first test region overlapping edges of the first surface, a plurality of first dummy pads electrically connected to each other, a plurality of second dummy pads positioned adjacent to the plurality of first dummy pads, wherein each second dummy pad of the plurality of second dummy pads is floated, and a first alignment key positioned adjacent to the plurality of first dummy pads and the plurality of second dummy pads; and a second semiconductor chip including: a second test region overlapping the first test region with at least a portion on a second surface of a second substrate facing the first surface of the first substrate, a plurality of power pads having at least a part that overlaps the plurality of second dummy pads and configured to provide a test voltage, and a second alignment key corresponding to the first alignment key.

According to an aspect of the disclosure, a manufacturing method of a semiconductor package includes: bonding a first semiconductor chip onto a first surface of a second semiconductor chip at a wafer level using an alignment key; providing a test signal to the second semiconductor chip using a test pad arranged on a second surface of the second semiconductor chip opposite to the first surface of the second semiconductor chip; testing an alignment of a stacking structure including the first semiconductor chip and the second semiconductor chip by detecting a current corresponding to the test signal at the test pad; and sawing a wafer including the second semiconductor chip.

### BRIEF DESCRIPTION OF DRAWINGS

FIG. 1 is a top plan view showing a semiconductor package according to one or more embodiments.

FIG. 2 is a cross-sectional view showing a cross-section taken along a line A-A′ of FIG. 1.

FIG. 3 is a top plan view illustrating a first test region of FIG. 2.

FIG. 4 is a top plan view illustrating a second test region of FIG. 2.

FIG. 5 is a cross-sectional view showing a cross-section taken along a line B-B′ of FIG. 3 and FIG. 4.

FIG. 6 is a cross-sectional view showing a cross-section taken along a line C-C′ of FIG. 3 and FIG. 4.

FIG. 7 is a cross-sectional view showing a cross-section taken along a line D-D′ of FIG. 3 and FIG. 4.

FIG. 8 is a cross-sectional view showing a semiconductor package according to one or more embodiments.

FIG. 9 is a cross-sectional view showing a semiconductor package according to one or more embodiments.

FIG. 10 is a top plan view illustrating a first test region of FIG. 9.

FIG. 11 is a top plan view illustrating a second test region of FIG. 9.

FIG. 12 is a top plan view showing a semiconductor package according to one or more embodiments.

FIG. 13 is a cross-sectional view showing a cross-section taken along a line E-E′ of FIG. 12.

FIG. 14 is a flowchart showing a manufacturing method of a semiconductor package according to one or more embodiments.

FIG. 15 to FIG. 18 are views for explaining a manufacturing method of a semiconductor package according to one or more embodiments.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

Descriptions of parts not relating to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses.

In addition, unless explicitly described to the contrary, the word “comprise”, and variations such as “comprises” or “comprising”, will be understood to imply the inclusion of stated elements but not the exclusion of any other elements.

In one or more examples, a specific number stated in a claim, even if explicitly cited within the claim, should not be construed as limiting the specific number in a claim where such citation does not exist. For example, to aid an understanding, subsequent dependent claims could include phrases ‘at least one’ and ‘one or more’. However, the use of such a phrase should not be understood as a limitation described by the unclear article ‘one’ for the sake of one example.

In one or more examples, when the conventions such as ‘at least one of A, B, or C’ are used, these phrases will be well understood by those skilled in the art (i.e., ‘a system including at least one of A, B, or C’ includes means of A alone, B alone, C alone, A and B, A and C, B and C, and/or A, B and C together, but it is not limited to any one concept).. Letters and/or phrases including two or more separate selectable terms in the detailed description, or claims or drawings should be considered as possible to include one, or either, or both terms. For example, the phrase ‘A or B’ should be understood as including the possibilities ‘A’, or ‘B’ or ‘A and B’.

Terms such as “module,” “unit,” and “part” used in this document refer to a component that performs at least one function or operation, and such component may be implemented as a hardware or a software, or may be implemented by combining a hardware and a software.

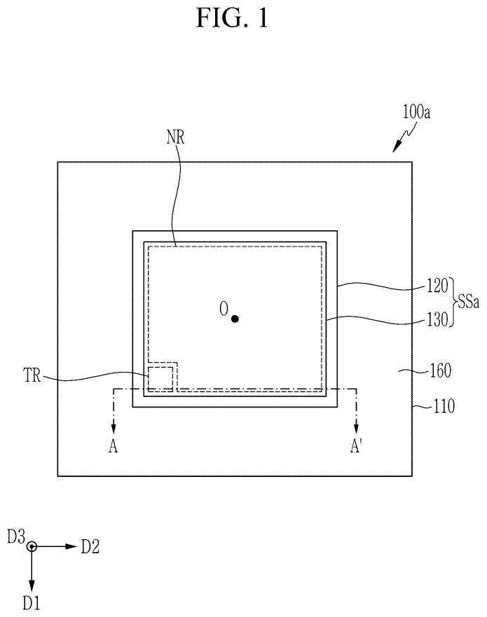

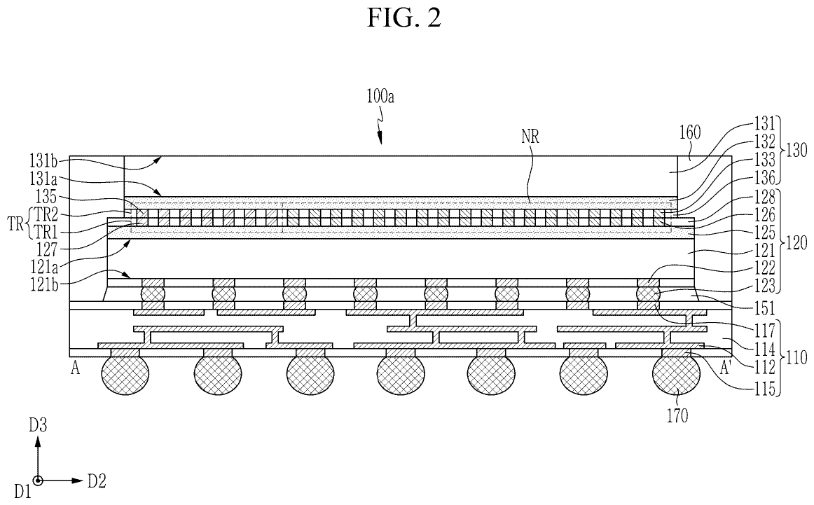

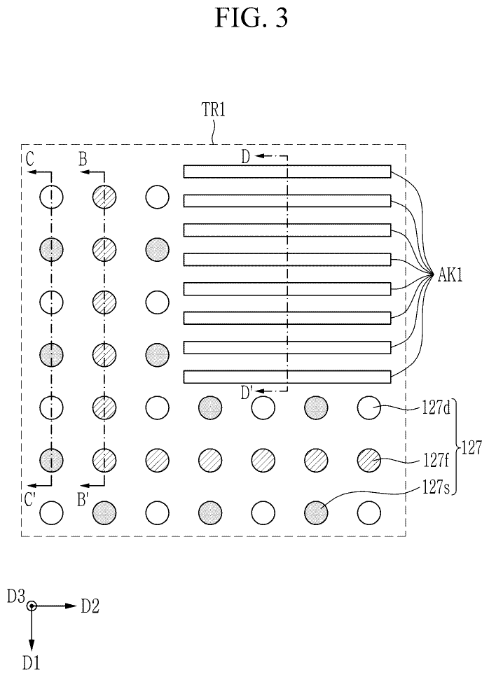

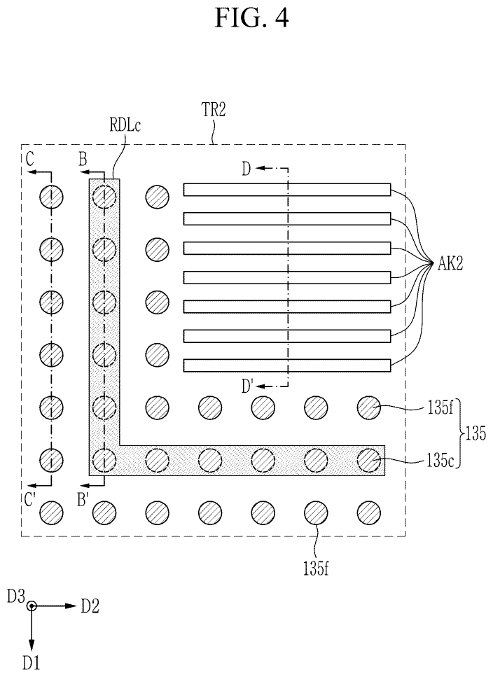

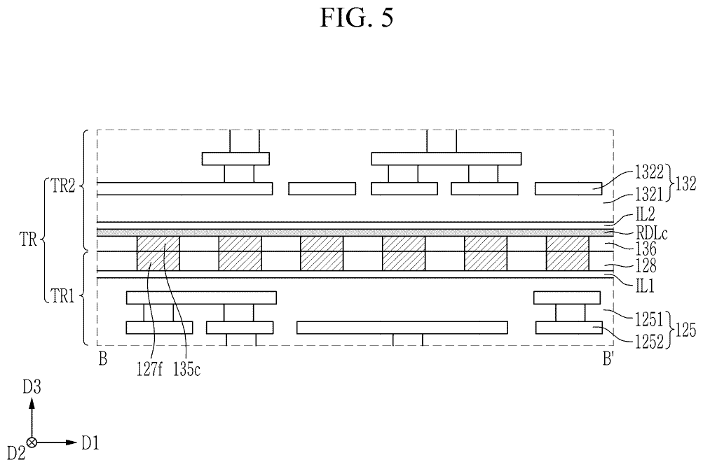

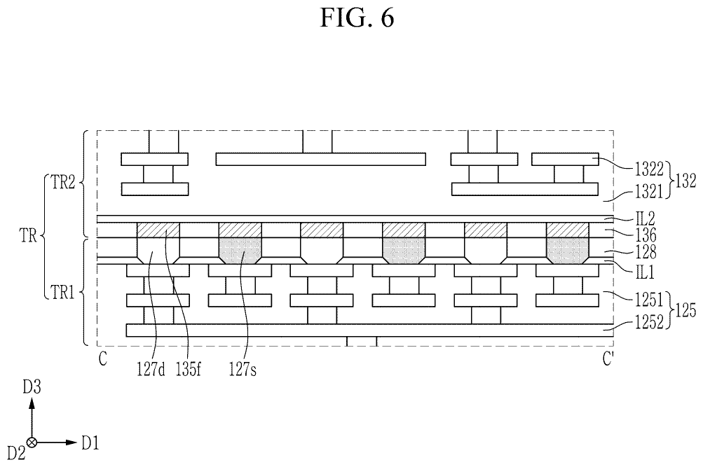

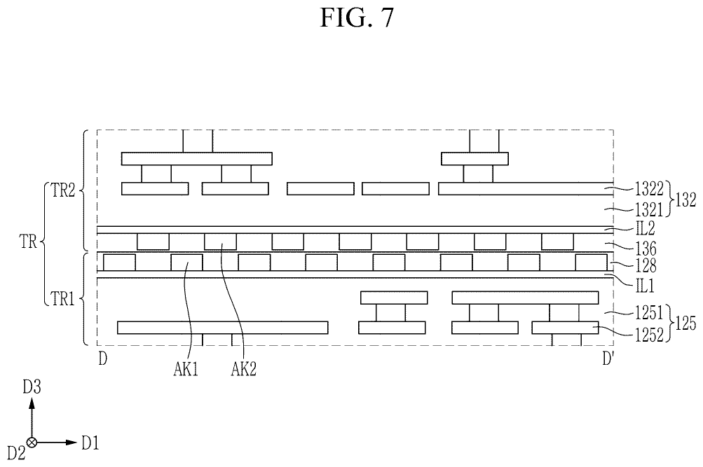

FIG. 1 is a top plan view showing a semiconductor package according to one or more embodiments. FIG. 2 is a cross-sectional view showing a cross-section taken along a line A-A′ of FIG. 1. FIG. 3 is a top plan view illustrating a first test region of FIG. 2. FIG. 4 is a top plan view illustrating a second test region of FIG. 2. FIG. 5 is a cross-sectional view showing a cross-section taken along a line B-B′ of FIG. 3 and FIG. 4. FIG. 6 is a cross-sectional view showing a cross-section taken along a line C-C′ of FIG. 3 and FIG. 4. FIG. 7 is a cross-sectional view showing a cross-section taken along a line D-D′ of FIG. 3 and FIG. 4.

Specifically, FIG. 5 shows the cross-section of a test region TR along the line B-B′. FIG. 6 shows the cross-section of the test region TR along the line C-C′. FIG. 7 shows the cross-section of the test region TR along the line D-D′.

Referring to FIG. 1 to FIG. 6, a semiconductor package 100a may include a stacking structure SSa including a first semiconductor chip 120 and a second semiconductor chip 130 stacked on the first semiconductor chip 120. In one or more examples, the semiconductor package 100a may further include a package substrate 110 on which the stacking structure SSa is mounted, external connection terminals 170 provided on the bottom surface of the package substrate 110, and a sealing member 160. As illustrated in FIG. 1, the second semiconductor chip 130 has smaller dimensions than the first semiconductor chip 120. However, as understood by one of ordinary skill in the art, the embodiments are not limited to this configuration. For example, the second semiconductor chip 130 may have the same size as the first semiconductor chip 120, or may have larger dimensions than the first semiconductor chip.

In one or more examples, the semiconductor package 100a may be a multi-chip package (MCP) that includes different types of semiconductor chips. According to one or more embodiments, the semiconductor package 100a may be a package (e.g., System In Package, SIP) that is a system having an independent function by stacking or arranging the plurality of semiconductor chips in one package.

The package substrate 110 may mount the stacking structure SSa placed thereon. The package substrate 110 may redistribute the conductive pads 122 of the first semiconductor chip 120 in the stacking structure SSa by extending them to the external region. Accordingly, the package substrate 110 may be referred to as a redistribution substrate. In one or more examples, according to one or more embodiments, the package substrate 110 may be referred to as a board, or a board substrate.

According to one or more embodiments, the package substrate 110 may be a ceramic substrate, a PCB, an organic substrate, an interposer substrate, etc. In one or more examples, according to one or more embodiments, the package substrate 110 may be manufactured based on an active wafer, such as a silicon wafer.

According to one or more embodiments, the package substrate 110 may include a wiring structure 112 and a substrate insulation layer 114 including the wiring structure 112.

The wiring structure 112 may include a redistribution lines and a via. The redistribution lines may be arranged in a multi-layer structure with a third direction D3 as a reference, and the wiring lines between the adjacent layers in the third direction D3 may be connected to each other through the via. An external connection terminal 170 may be arranged on the lower surface of the substrate insulation layer 114. The external connection terminal 170 may be arranged on the external connection pad 115 and connected to the wiring structure 112 through the external connection pad 115. In one or more examples, the external connection terminal 170 may be electrically connected to the stacking structure SSa via the external connection pad 115, the wiring structure 112, and the substrate pad 117.

The substrate insulation layer 114 may include an insulating material, for example, a thermosetting resin such as an epoxy resin, or a thermoplastic resin such as polyimide, and may further include an inorganic filler. In one or more examples, the substrate insulation layer 114 may include prepreg, ABF (Ajinomoto Build-up Film), or FR-4, BT (Bismaleimide Triazine) resin, or PID (Photo Imageable Dielectric) resin, and may further include an inorganic filler.

As shown in FIG. 2, the external connection terminal 170 may be placed on the center region of the lower surface of the substrate insulation layer 114, which overlaps the stacking structure SSa in a plane, and on the outer region of the lower surface of the substrate insulation layer 114 using the center region as a reference. The package substrate 110 may have a function of relocating the external connection terminal 170 to the wider portion than the lower surface of the stacking structure SSa through the wiring structure 112. In this way, a package structure in which the external connection terminal 170 may be widely arranged beyond the lower surface of the stacking structure SS, for example the first semiconductor chip 120, is referred to as a fan-out (FO) package structure. As understood by one of ordinary skill in the art, a fan-out package is a technique that spreads out connections from a chip's surface, which allows for more external I/Os and a thinner package. According to one or more embodiments, the external connection terminal 170 may be a solder ball, but is not limited thereto.

According to one or more embodiments, the package substrate 110 may be formed at a wafer level and may be included as a component of the semiconductor package 100a through an individualization such as a sawing. For example, when the package substrate 110 is wafer-based, the semiconductor package 100a may be referred to as FO-WLP (FO-Wafer Level Package). According to one or more embodiments, the package substrate 110 may be formed in a panel level and be included as a component of the semiconductor package 100a through the individualization by a sawing or the like. Accordingly, the semiconductor package 100a may be referred to as a FO-PLP (FO-Panel Level Package).

According to one or more embodiments, the stacking structure SSa may include a first semiconductor chip 120 as a logic chip and a second semiconductor chip 130 as a logic chip, which are sequentially stacked in the third direction D3, and each of the first semiconductor chip 120 and the second semiconductor chip 130 may include logic circuits that operate as different function blocks.

The first semiconductor chip 120 and the second semiconductor chip 130 may be operated as a single processor. For example, the first semiconductor chip 120 and the second semiconductor chip 130 may form a distributed architecture. According to one or more embodiments, each of the first semiconductor chip 120 and the second semiconductor chip 130 may be a chiplet that performs one or more functions of a processor chip such as an ASIC or an AP (Application Processor) as a part of a host (Host) such as an SOC. However, the embodiments are not limited to this configuration.

According to one or more embodiments, the first semiconductor chip 120 may be a logic chip, and the second semiconductor chip 130 may be a memory chip. The first semiconductor chip 120 may be a logic chip including a logic circuit, and the logic chip may be a controller that controls memory devices of the second semiconductor chip 130.

According to one or more embodiments, the first semiconductor chip 120 and the second semiconductor chip 130 may be chips having different areas in a plane. According to one or more embodiments, the first semiconductor chip 120 arranged at the lower part may be arranged more widely in a plane than the second semiconductor chip 130, and the semiconductor package 100a may be referred to as an X-Cube, CoWoS (Chip on Wafer on Substrate) package.

In the drawing, the semiconductor package 100a is depicted as a multi-chip package including first and second semiconductor chips 120, and 130, two stacked, but is not limited thereto and, for example, the semiconductor package may include 4, 8, 12, or 16 stacked semiconductor chips. Furthermore, the semiconductor package may include multiple stacks.

The first semiconductor chip 120 may include a first substrate 121, a conductive pad 122, a bump 123, a first wiring layer 125, a plurality of first signal power bonding pads 126, a plurality of first bonding pads 127, a first alignment key AK1.

The first substrate 121 may have a first surface 121a and a second surface 121b which are opposed to each other. The first surface 121a may be an active surface and face the second semiconductor chip 130. The second surface 121b may be an inactive surface and face the package substrate 110. As the active surface of the first substrate 121, circuit elements may be arranged on the first surface 121a of the first substrate 121. The first surface 121a may be referred to as a front side surface where the circuit elements are arranged, and the second surface 121b may be referred to as a backside surface.

The first substrate 121 may include a bulk silicon, a silicon-on-insulator (SOI), silicon germanium, silicon germanium on insulator (SGOI), indium antimony, lead tellurium compound, indium arsenic, indium phosphide, gallium arsenic or gallium antimony.

According to one or more embodiments, the second surface 121b may be an active surface of the first substrate 121 on which the circuit elements are arranged, and when the second surface 121b is the active surface, a wiring layer may be additionally arranged between the second surface 121b and the conductive pad 122.

The conductive pad 122 may be arranged on the second surface 121b of the first substrate 121 (e.g., the back surface). The conductive pads 122 may be arranged in array formations on the second surface 121b.

According to one or more embodiments, at least a portion of the conductive pad 122 may be disposed on a surface where a through electrode of the first substrate 121 is exposed. At least a portion of the conductive pad 122 may be electrically interconnected with the plurality of first signal power bonding pads 126 and the plurality of first bonding pads 127 via a through electrode. The conductive pad 122 may include a power pad providing a power voltage, a signal pad providing a signal, and a test pad for an electrical die sorting (EDS) inspection or for testing the alignment of the stacking structure SSa. According to one or more embodiments, the conductive pad 122, which is the test pad, may be electrically connected to at least a portion of the first bonding pad 127 via the through electrode. In one or more examples, an EDS inspection may refer to a process in semiconductor manufacturing where individual chips on a wafer are electrically tested to identify and separate defective chips from functional ones. The EDS inspection may be performed by contacting a wafer's contact pads with a probe car with one or more pins, thereby allowing electrical signals to be sent through a semiconductor chip.

The bump 123 may be placed on conductive pad 122 and bonded to the substrate pad 117. The conductive pad 122 and the substrate pad 117 may be electrically connected through the bump 123. According to one or more embodiments, the bump 123 may be a solder bump produced by a screen printing method or a deposition method, or a micro bump including a metal layer disposed by a plating method. However the embodiments are not limited to these methods.

A first underfill member 151 may be interposed between the package substrate 110 and the first semiconductor chip 120. For example, the first underfill member 151 may include an epoxy material to reinforce the gap between the package substrate 110 and the first semiconductor chip 120.

The first wiring layer 125 may be disposed on a first surface 121a. Referring to FIG. 5 to FIG. 7 together, the first wiring layer 125 may include a first insulation layer 1251 including a plurality of buffer films and a plurality of insulation layers alternately disposed in the third direction D3. For example, the buffer film may include silicon nitride, silicon carbon nitride, SiCON, etc. The insulation layer may include silicon oxide, carbon doped silicon oxide, silicon carbon nitride (SiCN), etc. According to one or more embodiments, the plurality of buffer films and the plurality of insulation layers may be arranged as one material layer. For example the plurality of buffer films and the plurality of insulations layers may be stacked together to form a single layer.

The first wiring layer 125 may include a first wiring structure 1252 of a multi-layer structure inside. For example, the first wiring structure 1252 may include a plurality of wiring lines vertically stacked in the third direction D3 in the first insulation layer 1251 and a plurality of vias connecting the plurality of stacked wiring lines.

The first wiring structure 1252 may include a conductive metal material, for example, aluminum (Al), copper (Cu), tin (Sn), nickel (Ni), gold (Au), platinum (Pt), or an alloy thereof.

The plurality of first signal power bonding pads 126 and the plurality of first bonding pads 127 may be arranged on the first wiring layer 125, and at least parts of the plurality of first signal power bonding pads 126 and the plurality of first bonding pads 127 may be exposed and uncovered by a first passivation layer 128. In one or more examples, the first passivation layer 128 may cover the upper and side surfaces of the first alignment key AK1.

In one or more examples, the first passivation layer 128 may include a plurality of stacked insulation layers. For example, the first passivation layer 128 may include an organic passivation layer including an oxide layer and an inorganic passivation layer including a nitride layer, which are sequentially stacked. The first passivation layer 128 may include silicon oxide, silicon nitride, silicon nitride, etc. According to one or more embodiments, the first insulation layer IL1 interposed between the first passivation layer 128 and the first wiring layer 125 may be a lowermost layer of the passivation layer. As understood by one or ordinary skill in the art, a passivation layer may serve the function of protecting an active surface of a semiconductor from an external environment, thereby improving long term reliability and performance of semiconductors.

The plurality of first signal power bonding pads 126 may be arranged in a normal region NR of the first semiconductor chip 120 on the first wiring layer 125. In one or more examples, the normal region NR may be a region where a signal power pad that performs a function of providing a power or a signal passage between the first semiconductor chip 120 and the second semiconductor chip 130 is placed, and may overlap, in a plane, the center O of the second semiconductor chip 130 placed above. Even if a warpage occurs in the semiconductor package 100a, the stacking structure SSa may operate normally because the plurality of first signal power bonding pads 126 are arranged in the normal region NR, which is the central region.

The plurality of first signal power bonding pads 126 may have a shape of a circle in a plane perspective, but is not limited thereto and may be transformed into various shapes such as an octagon or a quadrangle, according to one or more embodiments.

The plurality of first signal power bonding pads 126 may include a conductive metal material, and may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or any suitable alloy thereof known to one of ordinary skill in the art.

In one or more examples, the plurality of first signal power bonding pads 126 may be electrically connected to the first wiring structure 1252 and may be electrically connected to the circuit elements or the through electrodes in the first substrate 121 via the first wiring structure 1252.

The plurality of first bonding pads 127 may be arranged in the first test region TR1 of the first semiconductor chip 120 on the first wiring layer 125. The first test region TR1 may be a region where test pads for the EDS inspection process for the first semiconductor chip 120, an alignment key, and a dummy pad for performing an alignment test with the second semiconductor chip 130 are placed, and may overlap, in a plane, the center O of the second semiconductor chip 130. In FIG. 1 and FIG. 2, the first test region TR1 is depicted as being arranged in a quadrangle shape on one edge of the first semiconductor chip 120, but according to one or more embodiments, the number and shape of the regions may be variously changed.

The plurality of first bonding pads 127 may include a plurality of first floating dummy bonding pad 127f, a plurality of first power pad 127d, and a plurality of second power pad 127s.

The plurality of first bonding pads 127 may have the shape of a circle in a plane perspective. However, as understood by one of ordinary skill in the art, the embodiments are not limited to this configuration, where the bonding pads may be transformed into various shapes such as an octagon or a quadrangle, according to one or more embodiments. The plurality of first bonding pads 127 may include a conductive metal material, and may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or any suitable alloy known to one or ordinary skill in the art.

Referring to FIG. 3 and FIG. 5 together, the plurality of first floating dummy bonding pads 127f may be arranged in an ‘L’ shape in the first test region TR1. At least a portion of the plurality of first floating dummy bonding pads 127f may be arranged along the first direction D1, and at least a portion of the plurality of first floating dummy bonding pads 127f may be arranged along the second direction D2. As understood by one of ordinary skill in the art, a floating pad is a pad that is not connected to any other terminal such as to a terminal providing a voltage or a terminal connected to ground.

The plurality of first floating dummy bonding pads 127f may be separated from the first wiring structure 1252 through the first insulation layer IL1 and the first insulation layer 1251, so that the plurality of first floating dummy bonding pads 127f and the first wiring structure 1252 may be electrically isolated from each other. In one or more examples, the plurality of first floating dummy bonding pads 127f may be electrically isolated from each other and may be floated by the first insulation layer 1251.

Referring to FIG. 3 and FIG. 6 together, the plurality of first power pads 127d and a plurality of second power pads 127s may provide test signals for an alignment test for the stacking structure SSa. The test signal may include a test voltage and a ground voltage in a DC form, and for example, the plurality of first power pads 127d may each provide the test voltage and the plurality of second power pads 127s may each provide the ground voltage.

The plurality of first and second power pads 127d and 127s may be placed adjacent to the plurality of first floating dummy bonding pads 127f in the first test region TR1. For example, the plurality of first and second power pads 127d and 127s may be arranged in an ‘L’ shape, adjacent to each other on both sides of the plurality of first floating dummy bonding pads 127f.

The plurality of first power pads 127d and the plurality of second power pads 127s may be alternately arranged with each other. At least a portion of the plurality of first power pads 127d and at least a portion of the plurality of second power pads 127s may be arranged in a line in the first direction D1, and in the line arrangement, the first power pads 127d and the second power pads 127s may be arranged alternately. For example, three first power pads 127d and three second power pads 127s are arranged in the line C-C′ of FIG. 3, and in the line arrangement, the first power pads 127d and the second power pads 127s may be arranged alternately. As understood by one of ordinary skill in the art, the embodiments are not limited to the arrangement illustrated in FIG. 3. For example, each L shaped pattern may alternate between two or more first power pads 127d and two or more second power pads 127s. In one or more examples, each L shaped pattern may consist of only the first power pads 127d or the second power pads 127s.

The plurality of first and second power pads 127d and 127s may each be connected to the first wiring structure 1252. The plurality of first and second power pads 127d and 127s may be in contact with a portion of the first wiring structure 1252 that is exposed and uncovered by the first insulation layer IL1.

The plurality of first and second power pads 127d and 127s, respectively, may be electrically connected to the conductive pad 122 disposed on the second surface 121b of the first substrate 121, respectively, via a first wiring structure 1252. According to one or more embodiments, each of the plurality of first and second power pads 127d and 127s may be electrically connected to the test pad disposed on the second surface 121b of the first substrate 121 via the first wiring structure 1252.

Referring to FIG. 3 and FIG. 7 together, the first alignment key AK1 may be placed adjacent to the plurality of first bonding pads 127 in the first test region TR1. The first alignment key AK1 may be a pattern photographed to measure a die-to-die alignment as an overlay key. The first alignment key AK1 may include a pattern in a form of bars arranged in a plurality of rows or columns, but is not limited thereto, and according to one or more embodiments, it may be variously changed into a cross, triangle, quadrangle, octagon, etc. As an example, FIG. 3 illustrates that the first alignment key AK1 may include a seven-bar pattern extending in the second direction D2 and arranged in the first direction D1.

The first alignment key AK1 may be placed on the first insulation layer IL1 and covered by the first passivation layer 128. The thickness of the first alignment key AK1 in the first direction D1 may be thicker than that of the first wiring structure 1252, and may be determined by considering a resolution of an imaging camera of a die bonding device.

The first alignment key AK1 may be a conductive pattern including gold (Au), silver (Ag), copper (Cu), nickel (Ni) or aluminum (Al), but according to one or more embodiments, the first alignment key AK1 may be an insulation layer pattern including an insulating material.

The second semiconductor chip 130 may include a second substrate 131, a second wiring layer 132, a plurality of second signal power bonding pad 133, a plurality of second bonding pad 135, and a second alignment key AK2.

The second substrate 131 may have a third face 131a and a fourth face 131b which are opposed to each other. The third surface 131a may be an active surface and may face the first surface 121a of the first semiconductor chip 120. The fourth side 131b may be an inactive side. As the active surface of the second substrate 131, circuit elements may be arranged on the third surface 131a of the second substrate 131. The third surface 131a may be referred to as a front side surface where the circuit elements are arranged, and the fourth surface 131b may be referred to as a backside surface.

The second substrate 131 may include bulk silicon, silicon-on-insulator (SOI), silicon germanium, silicon germanium on insulator (SGOI), indium antimony, lead tellurium compound, indium arsenic, indium phosphide, gallium arsenic or gallium antimony.

Referring to FIG. 5 to FIG. 7 together, the second wiring layer 132 may be disposed on the third surface 131a and may include a second insulation layer 1321 including a plurality of buffer films and a plurality of insulation layers alternately disposed in the third direction D3. For example, the buffer film may include silicon nitride, silicon carbon nitride, SiCON, etc. The insulation layer may include silicon oxide, carbon doped silicon oxide, silicon carbon nitride (SiCN), etc. According to one or more embodiments, the plurality of buffer films and the plurality of insulation layers may be arranged as one material layer.

The second wiring layer 132 may include a second wiring structure 1322 of a multi-layer structure inside. For example, the second wiring structure 1322 may include a plurality of wiring lines vertically stacked in the third direction D3 in the second insulation layer 1321 and a plurality of vias connecting the plurality of stacked wiring lines.

The second wiring structure 1322 may include a conductive metal material, such as aluminum (Al), copper (Cu), tin (Sn), nickel (Ni), gold (Au), platinum (Pt), or an alloy thereof.

The plurality of second signal power bonding pads 133 and the plurality of second bonding pads 135 may be arranged on the second wiring layer 132, and at least parts of the plurality of second signal power bonding pads 133 and the plurality of second bonding pads 135 are not covered by the second passivation layer 136 such that the parts of the plurality of second signal power bonding pads 133 and the plurality of second bonding pads 135 remain exposed. The second passivation layer 136 may cover the upper and side surfaces of the second alignment key AK2.

At least a portion of the second passivation layer 136 may overlap the first passivation layer 128 in the third direction D3. The second passivation layer 136 and the first passivation layer 128 may be in contact with each other. The second passivation layer 136 and the first passivation layer 128 may be bonded to each other by a high temperature annealing process while being in contact with each other, and may have a strong junction strength as a part of the bonding structure for the stacking structure SSa.

In one or more examples, the second passivation layer 136 may include a plurality of stacked insulation layers. For example, the second passivation layer 136 may include an organic passivation layer including an oxide layer and an inorganic passivation layer including a nitride layer, which may be sequentially laminated. The second passivation layer 136 may include silicon oxide, silicon nitride, silicon nitride, etc. According to one or more embodiments, the second insulation layer IL2 interposed between the second passivation layer 136 and the second wiring layer 132 may be a lowermost layer of the passivation layer.

The plurality of second signal power bonding pads 133 may be arranged in the normal region NR of the second semiconductor chip 130 on the second wiring layer 132. In one or more examples, the normal region NR may be a region where a signal power pad that performs the function of providing a power or a signal passage between the first semiconductor chip 120 and the second semiconductor chip 130 is placed, and may overlap in a plane the center O of the second semiconductor chip 130 placed above. Even if a warpage occurs in the semiconductor package 100a, the stacking structure SSa may operate normally because the plurality of second signal power bonding pads 133 are arranged in the normal region NR, which is the central region.

The plurality of second signal power bonding pads 133 may have, in a plane perspective, a shape of a circle, but is not limited thereto, and may have a shape corresponding to the plurality of first signal power bonding pads 126.

The plurality of second signal power bonding pads 133 may include a conductive metal material, and may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or an alloy thereof.

In one or more examples, the plurality of second signal power bonding pads 133 may be electrically connected to the second wiring structure 1322 and may be electrically connected to circuit components within the second substrate 131 via the second wiring structure 1322.

The plurality of second signal power bonding pads 133 may overlap the plurality of first signal power bonding pads 126 in a plane, and the plurality of second signal power bonding pads 133 and the plurality of first signal power bonding pads 126 may be directly bonded in a pad-to-pad manner by a copper-copper hybrid bonding (a Cu—Cu hybrid bonding) method. For example, one pad is stacked on top of another pad where a copper-to-copper interconnect is used to provide a connection between the pads. The plurality of second signal power bonding pads 133 and the plurality of first signal power bonding pads 126 may be in direct contact with each other without a bump arrangement, and form a bonding structure together with the second passivation layer 136 and the first passivation layer 128.

The plurality of second bonding pads 135 may be arranged in the second test region TR2 of the second semiconductor chip 130 on the second wiring layer 132. The second test region TR2 is a region where test pads for the EDS inspection process for the second semiconductor chip 130, alignment keys, and dummy pads for performing an alignment test with the first semiconductor chip 120 are placed, and may overlap in a plane the center O of the second semiconductor chip 130. In FIG. 1 and FIG. 2, the second test region TR2 is depicted as being arranged in a quadrangle shape at one edge of the second semiconductor chip 130, however, the embodiments are not limited to these configurations. According to one or more embodiments, the second test region TR2 corresponds to the first test region TR1 of the first semiconductor chip 120, and the number and shape of the regions may be variously changed to correspond to the first test region TR1. At least a portion of the second test region TR2 may be placed on the second semiconductor chip 130 by overlapping the first test region TR1 of the first semiconductor chip 120 in the third direction D3.

The plurality of second bonding pad 135 may include a plurality of chain dummy bonding pads 135c, and a plurality of second floating dummy bonding pads 135f.

The plurality of second bonding pads 135 may have, in a plane perspective, a shape of a circle, but is not limited thereto and may be transformed into various shapes corresponding to the plurality of first bonding pads 127. The plurality of first bonding pads 135 may include a conductive metal material, and may include copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or any suitable alloy known to one of ordinary skill in the art.

The plurality of second bonding pads 135 may overlap the plurality of first bonding pads 127 in a plane, and the plurality of second bonding pads 135 and the plurality of first bonding pads 127 may be directly bonded in a pad-to-pad manner by a copper-copper hybrid bonding (a Cu—Cu hybrid bonding) method. The plurality of second bonding pads 135 and the plurality of first bonding pads 127 may be in direct contact with each other without a bump arrangement, and form a bonding structure together with the second passivation layer 136 and the first passivation layer 128.

Referring to FIG. 3 and FIG. 5 together, the plurality of chain dummy bonding pads 135c may be arranged in an ‘L’ shape in the second test region TR2. In one or more examples, at least a portion of the plurality of chain dummy bonding pads 135c may be arranged along the first direction D1, and at least a portion of the plurality of chain dummy bonding pads 135c may be arranged along the second direction D2.

The plurality of chain dummy bonding pads 135c may be separated from the second wiring structure 1322 through the second insulation layer IL2 and the second insulation layer 1321 so that the plurality of chain dummy bonding pads 135c and the second wiring structure 1322 may be electrically isolated from each other.

In one or more examples, the plurality of chain dummy bonding pads 135c may be electrically connected to each other through a chain redistribution layer RDLc interposed between the second passivation layer 136 and the second insulation layer IL2. In one or more examples, at least a portion of the chain redistribution layer RDLc may overlap the plurality of chain dummy bonding pads 135c in the third direction D3, and may be arranged in a plane in an ‘L’ shape. The chain redistribution layer RDLc may be separated from the second wiring structure 1322 via the second insulation layer IL2 and the second insulation layer 1321, so that the chain redistribution layer RDLc and the second wiring structure 1322 may be electrically isolated from each other.

The plurality of chain dummy bonding pads 135c overlap the plurality of first floating dummy bonding pads 127f in a plane, and the plurality of chain dummy bonding pads 135c and the plurality of first floating dummy bonding pads 127f may be directly bonded in a pad-to-pad type by a copper-copper hybrid bonding method. The plurality of chain dummy bonding pads 135c and the plurality of first floating dummy bonding pads 127f may be in direct contact with each other without a bump arrangement, and form a bonding structure together with the second passivation layer 136 and the first passivation layer 128.

If the first semiconductor chip 120 and the second semiconductor chip 130 are aligned and bonded, the plurality of chain dummy bonding pads 135c and the plurality of first floating dummy bonding pads 127f, which correspond to each other, may be bonded by overlapping in the third direction D3. If the plurality of chain dummy bonding pads 135c and the plurality of first floating dummy bonding pads 127f are both bonded, a current may not be detected at the test pads even if a test signal is provided due to the floating state of the plurality of first floating dummy bonding pads 127f and the electrical separation from the plurality of first and second power pads 127d and 127s.

Referring to FIG. 3 and FIG. 6 together, the plurality of second floating dummy bonding pads 135f may be placed adjacent to the plurality of chain dummy bonding pads 135c in the second test region TR2. For example, the plurality of second floating dummy bonding pads 135f may be arranged in an ‘L’ shape, adjacent to each other on both sides of the plurality of chain dummy bonding pads 135c.

The plurality of second floating dummy bonding pads 135f are separated from the second wiring structure 1322 through the second insulation layer IL2 and the second insulation layer 1321, so that the plurality of second floating dummy bonding pads 135f and the second wiring structure 1322 may be electrically isolated from each other. In one or more examples, the second wiring structures 1322 may be electrically isolated from each other and floated by the second insulation layer 1321.

The plurality of second floating dummy bonding pads 135f may overlap in a plane the plurality of first and second power pads 127d and 127s, and the plurality of second floating dummy bonding pads 135f and the plurality of first and second power pads 127d and 127s may be directly bonded in a pad-to-pad fashion by a copper-copper hybrid bonding method. The plurality of second floating dummy bonding pads 135f and the plurality of first and second power pads 127d and 127s may be in direct contact with each other without a bump arrangement, and form a bonding structure together with the second passivation layer 136 and the first passivation layer 128.

If the first semiconductor chip 120 and the second semiconductor chip 130 are aligned and bonded, the plurality of second floating dummy bonding pads 135f and the plurality of first and second power pads 127d and 127s may be bonded by overlapping in the third direction D3. If the plurality of second floating dummy bonding pads 135f and the plurality of first and second power pads 127d and 127s are all bonded, a current may not be detected at the test pads even if a test signal is provided due to the floating state of the plurality of second floating dummy bonding pads 135f.

Referring to FIG. 4 and FIG. 7 together, the second alignment key AK2 may be positioned adjacent to the plurality of second bonding pads 135 in the second test region TR2. The second alignment key AK2 may be an overlay key, a pattern photographed to measure a die-to-die alignment together with the first alignment key AK1. The second alignment key AK2 may include a plurality of bar-shaped patterns arranged in rows or columns, but is not limited thereto, and may be variously changed in response to the first alignment key AK1 of the first test region TR1.

As an example, FIG. 4 illustrates that the second alignment key AK2 may include an eight-bar pattern extended in the second direction D2 and arranged in the first direction D1. Each pattern of the second alignment key AK2 may be placed on one side of each pattern of the first alignment key AK1 in an in-plane perspective. Each pattern of the second alignment key AK2 may be arranged non-overlapping with each pattern of the first alignment key AK1 with reference to the third direction D3.

The second alignment key AK2 may be placed on the second insulation layer IL2 and covered by the second passivation layer 136. The thickness of the second alignment key AK2 in the first direction D1 may be thicker than that of the second wiring structure 1322, and be determined by considering the resolution of the imaging camera of the die bonding device.

The second alignment key AK2 may be a conductive pattern including gold (Au), silver (Ag), copper (Cu), nickel (Ni) or aluminum (Al), but according to one or more embodiments, the second alignment key AK2 may be an insulation layer pattern including an insulating material.

The sealing member 160 may surround the side surface of the second semiconductor chip 130 on the first semiconductor chip 120. The sealing member 160 may cover at least a portion of the side surface of the second semiconductor chip 130 and the upper surface of the first semiconductor chip 120. The upper surface of the second semiconductor chip 130 (e.g., the fourth surface 131b, may be exposed and uncovered by the sealing member 160). For example, the sealing member 160 may include a thermosetting resin, etc.

If the first semiconductor chip 120 and the second semiconductor chip 130 are connected without being aligned, at least a portion of the plurality of first and second power pads 127d and 127s and at least a portion of the plurality of chain dummy bonding pads 135c may overlap in the third direction D3 and be bonded to each other. If the plurality of first and second power pads 127d and 127s and the plurality of chain dummy bonding pad 135c are bonded, at least a portion of the plurality of first and second power pads 127d and 127s, the plurality of chain dummy bonding pads 135c, and at least a portion of the chain redistribution layer RDLc may form a current path. If the first semiconductor chip 120 and the second semiconductor chip 130 are not aligned, a current may be detected at the test pad when a test signal is provided to the stacking structure SSa.

By arranging the plurality of first bonding pads 127 and the plurality of second bonding pads 135 in the test region TR, the semiconductor package 100a may easily perform an alignment test of the stacking structure SSa through the DC test utilizing the test pads without a separate dedicated circuit.

In addition, based on the chain connection of the plurality of chain dummy bonding pad 135c through the chain redistribution layer RDLc, and the plurality of first and second power pads 127d and 127s alternately arranged adjacent to the plurality of chain dummy bonding pad 135c, the semiconductor package 100a may effectively provide the alignment test results for the stacking structure SSa.

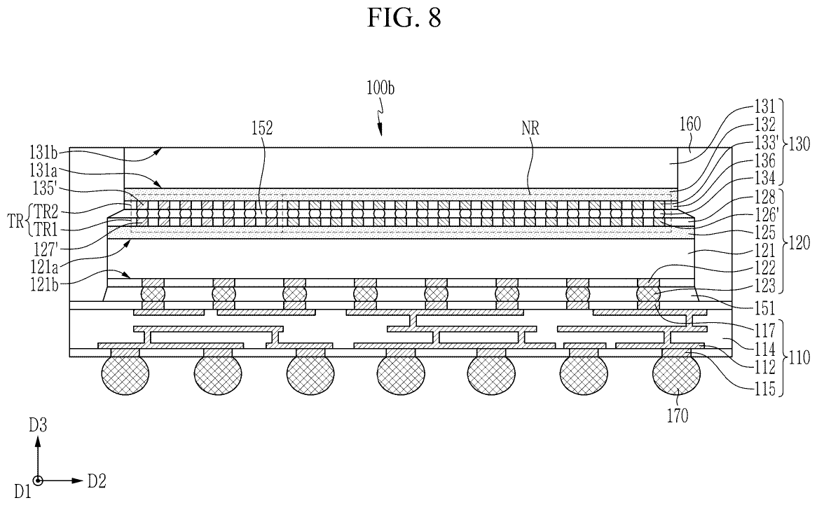

FIG. 8 is a cross-sectional view showing a semiconductor package according to one or more embodiments.

The semiconductor package 100b of FIG. 8 may correspond to the semiconductor package 100a of FIG. 1 to FIG. 7, and for ease of explanation, the semiconductor package 100b is described focusing on the differences from the semiconductor package 100a of FIG. 1 to FIG. 7.

Referring to FIG. 8, in the normal region NR, the first semiconductor chip 120 may be electrically connected to the second semiconductor chip 130 through the plurality of first signal power pads 126′ arranged on the first surface 121a. The plurality of first signal power pads 126′ may correspond to the plurality of first signal power bonding pads 126 of FIG. 1 to FIG. 7, and the plurality of first signal power pads 126′ is explained below with reference to the differences from the plurality of first signal power bonding pads 126.

In the normal region NR, the second semiconductor chip 130 may be electrically connected to the first semiconductor chip 120 through the plurality of second signal power pads 133′ arranged on the third surface 131a. The plurality of second signal power pad 133′ may correspond to the plurality of second signal power bonding pads 133 of FIG. 1 to FIG. 7, and the plurality of second signal power pads 133′ is explained below with reference to the difference from the plurality of second signal power bonding pad 133.

In the first test region TR1, the first semiconductor chip 120 may be electrically connected to the second semiconductor chip 130 through the plurality of first pads 127′ arranged on the first surface 121a. The plurality of first pad 127′ may correspond to the plurality of first bonding pads 127 of FIG. 1 to FIG. 7, and the plurality of first pad 127′ is explained below with reference to the difference between the plurality of first bonding pads 127 and the plurality of first pad 127.

In the second test region TR2, the second semiconductor chip 130 may be electrically connected to the first semiconductor chip 120 through the plurality of second pads 135′ arranged on the third surface 131a. The plurality of second pad 135′ may correspond to the plurality of first bonding pads 135 of FIG. 1 to FIG. 7, and the plurality of second pad 135′ is explained below with reference to the difference from the plurality of second bonding pad 135.

In the normal region NR, the conductive bump 134 of the second semiconductor chip 130 may be arranged on the plurality of second signal power pads 133′ and bonded to the plurality of first signal power pads 126′. The plurality of first signal power pads 126′ and the plurality of second signal power pads 133′ may be electrically connected via conductive bumps 134. According to one or more embodiments, the conductive bump 134 may be a micro bump including a metal layer disposed by a plating method, but is not limited thereto.

In the test region TR, the conductive bump 134 of the second semiconductor chip 130 may be arranged on the plurality of second pads 135′ and bonded to the plurality of first pads 127′. The plurality of first pads 127′ and the plurality of second pads 135′ may be electrically connected via the conductive bump 134. According to one or more embodiments, the conductive bump 134 may be a micro bump including a metal layer disposed by a plating method, however, the embodiments are not limited to these configurations.

The second underfill member 152 may be interposed between the first semiconductor chip 120 and the second semiconductor chip 130. The second underfill member 152 may be interposed between the first passivation layer 128 of the upper surface of the first semiconductor chip 120 and the second passivation layer 136 of the lower surface of the second semiconductor chip 130. For example, the second underfill member 152 may include an epoxy material to reinforce the gap between the first semiconductor chip 120 and the second semiconductor chip 130.

The second underfill member 152 may be used as an adhesive layer when bonding the first semiconductor chip 120 and the second semiconductor chip 130 using a thermal compression bonding (TCB) method in the stacking process of the first semiconductor chip 120 and the second semiconductor chip 130. According to one or more embodiments, the second underfill member 152 may be arranged in a molded underfill (MUF) manner.

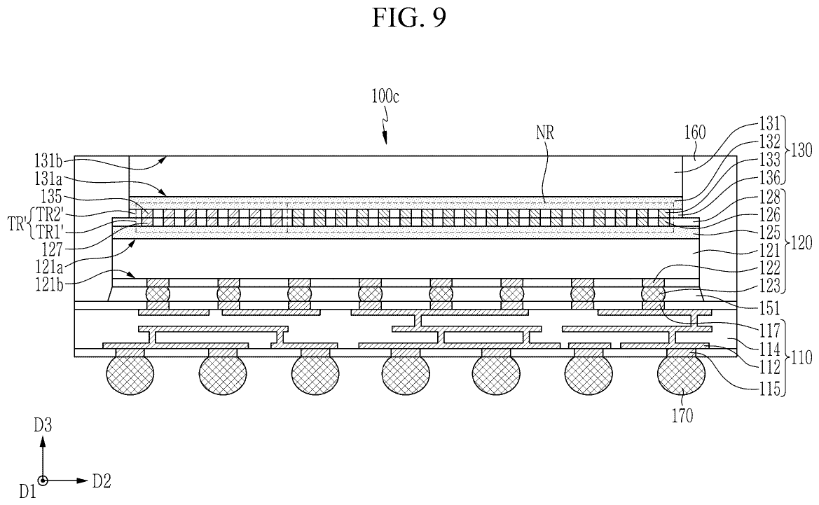

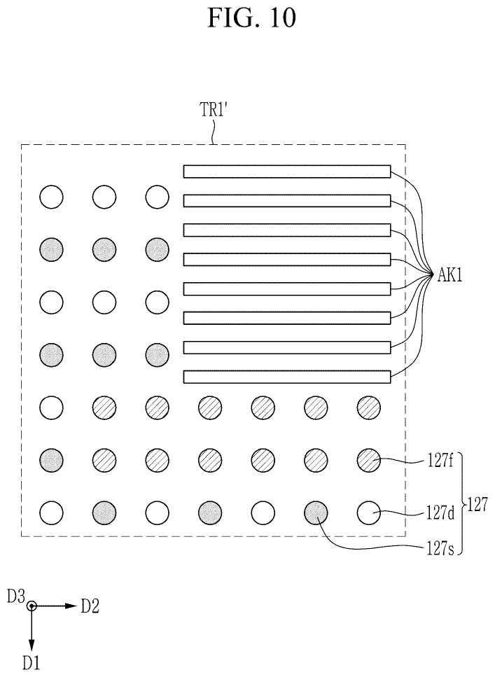

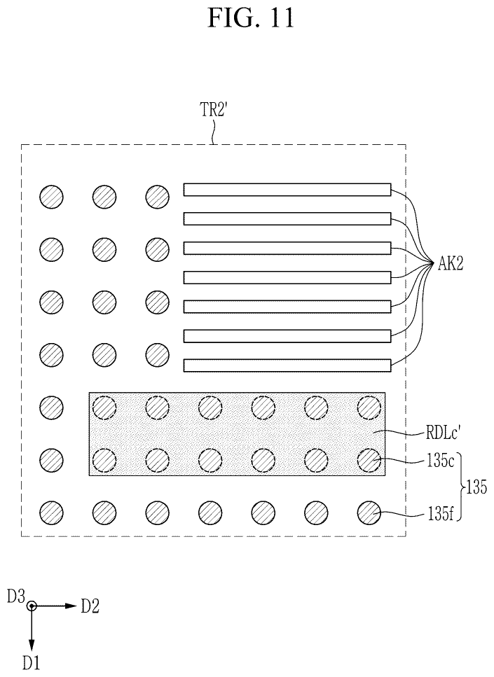

FIG. 9 is a cross-sectional view showing a semiconductor package according to one or more embodiments. FIG. 10 is a top plan view illustrating a first test region of FIG. 9. FIG. 11 is a top plan view illustrating a second test region of FIG. 9.

The semiconductor package 100c, the first test region TR1′, and the second test region TR2′ of FIG. 9 to FIG. 11 may respectively correspond to the semiconductor package 100a, the first test region TR1, and the second test region TR2 of FIG. 1 to FIG. 7, and for ease of explanation, the semiconductor package 100c is described focusing on the differences from the semiconductor package 100a of FIG. 1 to FIG. 7.

Referring to FIG. 9 to FIG. 11, the plurality of first floating dummy bonding pads 127f may be arranged in a bar shape in the first test region TR1′. The bar shape may include at least two columns. As an example, as illustrated in FIG. 10, the plurality of first floating dummy bonding pads 127f may be arranged along two columns adjacent in the first direction D1 in the second direction D2.

The plurality of first and second power pads 127d and 127s, respectively, may be placed adjacent to may plurality of first floating dummy bonding pad 127f in the first test region TR1′. As an example of FIG. 10, the plurality of first and second power pads 127d and 127s, respectively, may be arranged to surround the plurality of first floating dummy bonding pads 127f at the point where the plurality of first bonding pads 127 are arranged.

The plurality of chain dummy bonding pads 135c may be arranged in a bar shape in the second test region TR2′. The bar shape may include at least two columns. As an example, as illustrated in FIG. 11, the plurality of chain dummy bonding pads 135c may be arranged along two columns adjacent in the first direction D1 in the second direction D2.

At least a portion of the chain redistribution layer RDLc′ may overlap the plurality of chain dummy bonding pads 135c in the third direction D3, and may be arranged in a plane in a form of a bar.

The plurality of second floating dummy bonding pads 135f can be placed adjacent to a plurality of chain dummy bonding pads 135c in the second test region TR2′. As an example of FIG. 11, the plurality of second floating dummy bonding pads 135f may be arranged to surround the plurality of chain dummy bonding pads 135c at the point where the plurality of second bonding pads 135 are placed.

As illustrated in FIG. 10 and FIG. 11, the plurality of first floating dummy bonding pads 127f and the plurality of chain dummy bonding pads 135c may be arranged in the bar shape. However, according to one or more embodiments, the arrangement of the plurality of first floating dummy bonding pads 127f and the plurality of chain dummy bonding pads 135c may be changed in various ways. As the arrangement of the plurality of chain dummy bonding pads 135c changes, the shape of the chain redistribution layer that overlaps and contacts in a plane may also change.

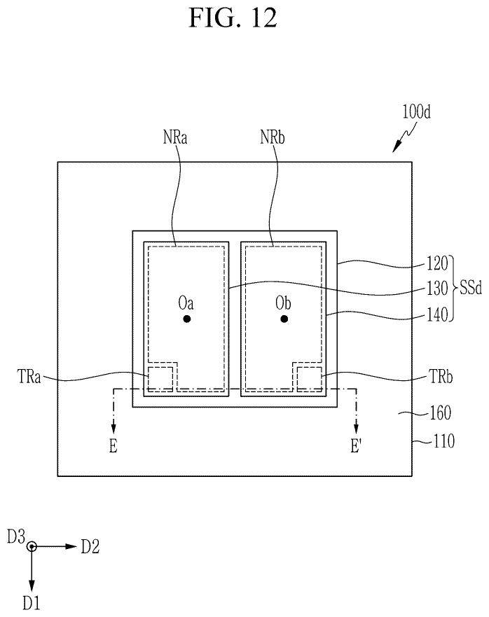

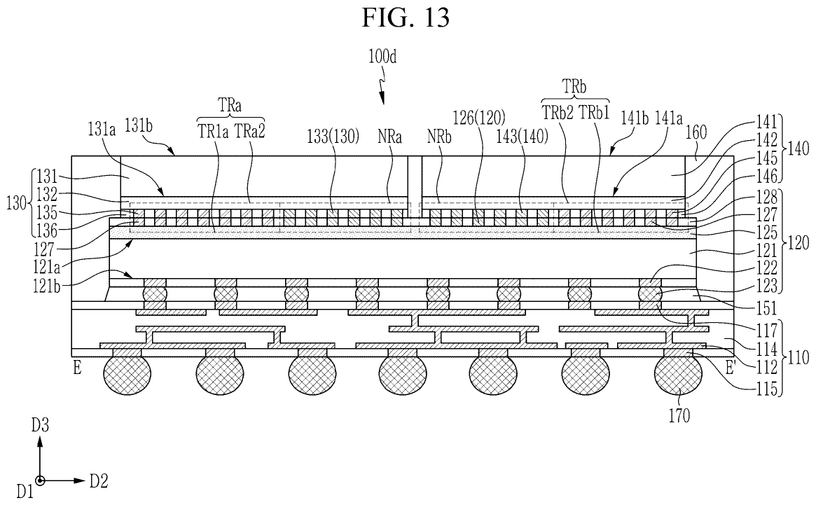

FIG. 12 is a top plan view showing a semiconductor package according to one or more embodiments. FIG. 13 is a cross-sectional view showing a cross-section taken along a line E-E′ of FIG. 12.

The semiconductor package 100d, the first semiconductor chip 120, the second semiconductor chip 130, the first normal region NRa, the first_first test region TRa1, and the first_second test region TRa2 of FIG. 12 to FIG. 13 may respectively correspond to the semiconductor package 100a, the first semiconductor chip 120, the second semiconductor chip 130, the normal region NR, the first test region TR1, and the second test region TR2 of FIG. 1 to FIG. 7, for ease of explanation, the semiconductor package 100d is described focusing on the differences from the semiconductor package 100a of FIG. 1 to FIG. 7.

Referring to FIG. 12 and FIG. 13, a semiconductor package 100d may include a stacking structure SSd including a first semiconductor chip 120, and second and third semiconductor chips 130, and 140 stacked on the first semiconductor chip 120, and the stacking structure SSd may be mounted on a package substrate 110. The second semiconductor chip 130 and the third semiconductor chip 140 may be arranged without overlapping each other in a plane on the first surface 121a of the first semiconductor chip 120.

The first semiconductor chip 120 may further include, compared to the first semiconductor chip 120 of FIG. 1 to FIG. 7, a second normal region NRb, a second_first test region TRb1, and a second_second test region TRb2 corresponding to the first normal region NRa, the first_first test region TRa1, and the first_second test region TRa2, respectively.

The second normal region NRb is a region where a signal power pad that performs the function of providing a power or passing signals between the first semiconductor chip 120 and the third semiconductor chip 140 is placed, and may overlap in a plane with the center Ob of the third semiconductor chip 140 placed above. Even if a warpage occurs in the semiconductor package 100d, the stacking structure SSd may operate normally because the plurality of first signal power bonding pads 126 are arranged in the normal regions NRa and NRb, which are the central region.

The second_first test region TRb1 may be a region where test pads for the EDS inspection process for the first semiconductor chip 120, an alignment key, and a dummy pad for performing an alignment test with the third semiconductor chip 140 are placed, and may overlap in a plane the center Ob of the third semiconductor chip 140. In FIG. 11 and FIG. 12, the second_first test region TRb1 is depicted as being arranged in a quadrangle shape on one edge of the first semiconductor chip 120, but according to one or more embodiments, the number and shape of the regions may be variously changed.

The third semiconductor chip 140 may be a logic chip and may include a logic circuit that operates as a different function block from the first semiconductor chip 120 and the second semiconductor chip 130. The first to third semiconductor chips 120 to 140 may be operated as a single processor, and each first to third semiconductor chip 120 to 140 may be a chip performing one or more functions of the processor chip. However, the embodiments are not limited to this configuration. For example, each of the first to third semiconductor chips 120 to 140 may be a processor controlling a different part of an electronic device. For example, if the electronic device is a Smart TV, a first processor may control display functions while a second processor controls power and communication functions.

The third semiconductor chip 140 may include a third substrate 141, a third wiring layer 142, a plurality of third signal power bonding pads 143, a plurality of third bonding pads 145, and a third alignment key corresponding to the alignment key of the second_first test region TRb1.

The third substrate 141 may have a fifth surface 141a and a sixth surface 141b that are opposed to each other. The fifth surface 141a may be an active surface and face the first surface 121a of the first semiconductor chip 120. The sixth surface 141b may be an inactive surface. Circuit elements may be arranged on the fifth surface 141a of the second substrate 141 as the active surface of the second substrate 141. The fifth surface 141a may be referred to as a front side surface where the circuit elements are arranged, and the sixth surface 141b may be referred to as a backside surface.

The third wiring layer 142 may be disposed on the fifth surface 141a and may include a third wiring structure including a third insulation layer including a plurality of buffer films and a plurality of insulation layers alternately disposed in the third direction D3, a plurality of wiring lines vertically stacked in the third direction D3 within the third insulation layer, and a plurality of vias connecting the plurality of stacked wiring lines.

The plurality of third signal power bonding pads 143 and the plurality of third bonding pads 145 may arranged on the third wiring layer 142, and at least parts of the plurality of third signal power bonding pads 143 and the plurality of third bonding pads 145 may be exposed and uncovered by the third passivation layer 146. The third passivation layer 146 may cover the upper and side surfaces of the fourth alignment key.

At least a portion of the third passivation layer 146 may overlap the first passivation layer 128 in the third direction D3. The third passivation layer 146 and the first passivation layer 128 may be in contact with each other. The third passivation layer 146 and the first passivation layer 128 may be bonded to each other by a high temperature annealing process while being in contact with each other, and may have a strong junction strength as a part of the bonding structure of the stacking structure SSa.

The plurality of third signal power bonding pads 143 may correspond to the plurality of second signal power bonding pads 133 and may be arranged in the second normal region NRb of the third semiconductor chip 140 on the third wiring layer 142. The second normal region NRb is a region where a signal power pad that performs the function of providing a power or passing signals between the first semiconductor chip 120 and the third semiconductor chip 140 is placed, and may overlap in a plane the center Ob of the third semiconductor chip 140 placed above. Even if a warpage occurs in the semiconductor package 100d, the stacking structure SSd may operate normally because the plurality of third signal power bonding pads 143 are arranged in the second normal region NRb.

The plurality of third signal power bonding pads 143 may overlap the plurality of first signal power bonding pads 126 in a plane, and the plurality of third signal power bonding pads 143 and the plurality of first signal power bonding pads 126 may be directly bonded in a pad-to-pad type by a copper-copper hybrid bonding method. The plurality of third signal power bonding pads 143 and the plurality of first signal power bonding pads 126 may be in direct contact with each other without a bump arrangement, and form a bonding structure together with the third passivation layer 146 and the first passivation layer 128.

The plurality of third bonding pads 145 may correspond to the plurality of second bonding pads 135 and may be arranged in the second_second test region TRb2 of the third semiconductor chip 140 on the third wiring layer 142. The second_second test region TRb2 is a region where test pads for the EDS inspection process for the third semiconductor chip 140, alignment keys, and dummy pads for performing an alignment test with the first semiconductor chip 120 are placed, and may not overlap in a plane with the center Ob of the third semiconductor chip 140. In FIG. 11 and FIG. 12, the second_second test region TRb2 is depicted as being arranged in a quadrangle shape at one edge of the third semiconductor chip 140, but is not limited thereto. According to one or more embodiments, the second_second test region TRb2 corresponds to the second_first test region TRb1 of the first semiconductor chip 120, and the number and shape of the regions may be variously changed to correspond to the second_first test region TRb1. At least a portion of the second_second test region TRb2 may be placed on the third semiconductor chip 140 by overlapping the second_first test region TRb1 of the first semiconductor chip 120 in the third direction D3.

The plurality of third bonding pads 145 may correspond to the plurality of second bonding pad 135. The plurality of third bonding pads 145 overlaps the plurality of first bonding pads 127 in a plane, and the plurality of third bonding pads 145 and the plurality of first bonding pads 127 may be directly bonded in a pad-to-pad type by a copper-copper hybrid bonding method. The plurality of third bonding pads 145 and the plurality of first bonding pads 127 may be in direct contact with each other without a bump arrangement, and form a bonding structure together with the third passivation layer 146 and the first passivation layer 128.

The sealing member 160 may surround the side surfaces of the second and third semiconductor chips 130 and 140 on the first semiconductor chip 120. The sealing member 160 may cover at least a portion of the side surfaces of the second and third semiconductor chips 130 and 140, and the upper surface of the first semiconductor chip 120. The upper surface of the third semiconductor chip 140, i.e., the sixth surface 141b, may be exposed and uncovered by the sealing member 160. For example, the sealing member 160 may include a thermosetting resin, etc.

If the first semiconductor chip 120 and the third semiconductor chip 140 are aligned and connected, even if a test signal is provided to the conductive pad 122 of the first semiconductor chip 120, a current may not be detected at the test pad.

If the first semiconductor chip 120 and the third semiconductor chip 140 are connected without being aligned, a current path for the test signal may be formed within the stacking structure SSd. If the first semiconductor chip 120 and the third semiconductor chip 140 are not aligned, a current may be detected at the test pad when a test signal is provided to the stacking structure SSd.

Through the arrangement of the plurality of first bonding pads 127 in the second_first test region TRb1 and the plurality of third bonding pads 145 in the second_second test region TRb2, the semiconductor package 100d may easily perform an alignment test of the stacking structure SSd through the DC test utilizing the test pads without a separate dedicated circuit.

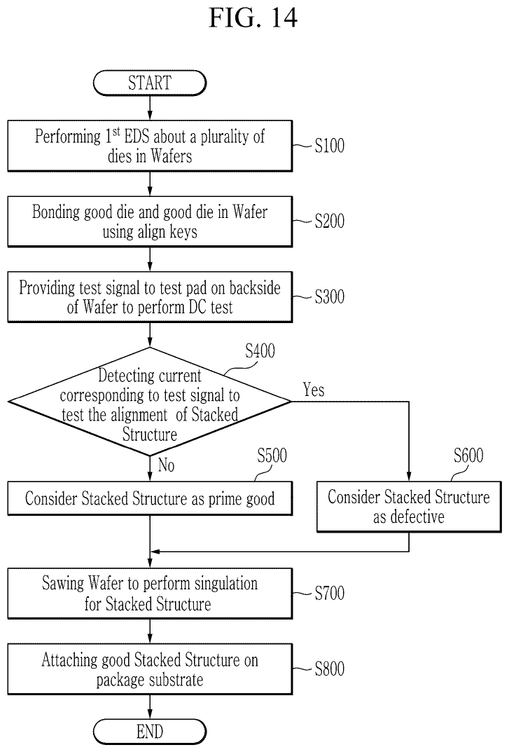

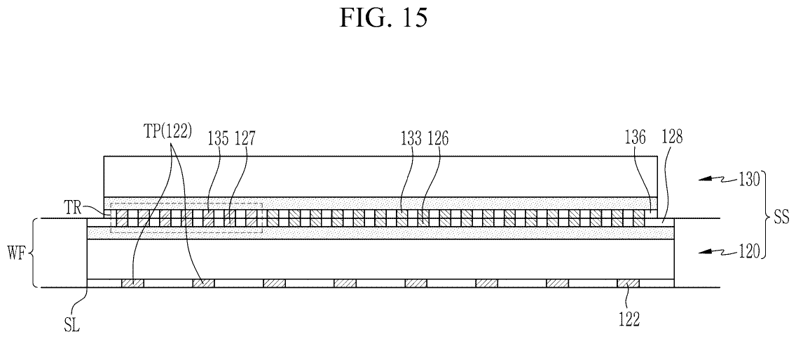

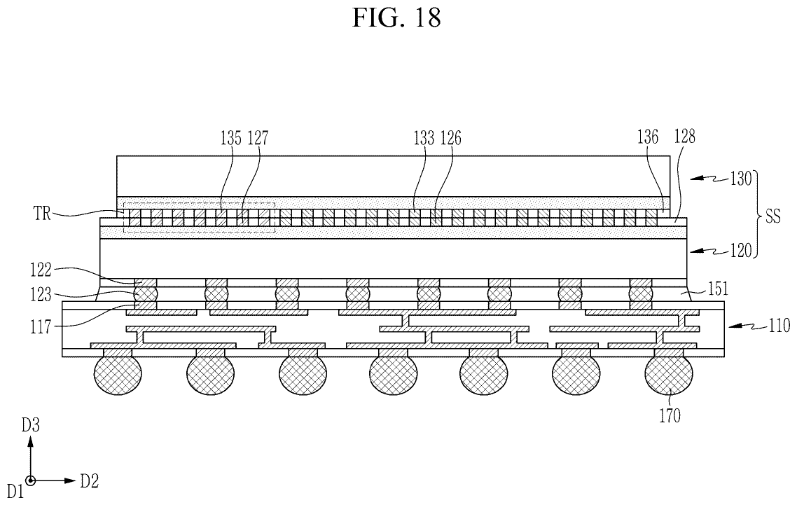

FIG. 14 is a flowchart showing a manufacturing method of a semiconductor package according to one or more embodiments. FIG. 15 to FIG. 18 are views for explaining a manufacturing method of a semiconductor package according to one or more embodiments.

Referring to FIG. 14 and FIG. 15, an EDS inspection is performed on the first semiconductor chip 120 and the second semiconductor chip 130 at a wafer (WF) level (S100).

Before the operation (S100), a preprocess for the first semiconductor chip 120 is performed at the wafer level, so that pads including a plurality of first signal power bonding pads 126 and a plurality of first bonding pads 127, etc., may be placed on the upper surface of the first semiconductor chip 120. Similarly, a preprocess for a second semiconductor chip 130 may be performed at the wafer (WF) level, so that pads including a plurality of second signal power bonding pads 133 and a plurality of second bonding pads 135 may be placed on the upper surface of the second semiconductor chip 130.

The first semiconductor chip 120 may be distinguished by a scribe line at the wafer level, and various electric characteristic tests may be performed on the first semiconductor chip 120 distinguished by the scribe line in the EDS inspection. Similarly, the second semiconductor chip 130 may be distinguished by a scribe line SL at the wafer (WF) level, and various electric characteristic tests may be performed on the second semiconductor chip 130 distinguished by the scribe line SL in the EDS inspection. By checking the status of the first and second semiconductor chips 120 and 130 through the results of the electric characteristic test, it is possible to determine whether the first and second semiconductor chips 120 and 130 are good products (good die).

For example, during the EDS inspection, probe pins of a probe card may be in contact with the test pads in the test region TR of the first and second semiconductor chips 120 and 130 to transmit test signals and detect electrical signals.

Using the alignment key, the first semiconductor chip 120, which is a good product, is bonded onto the second semiconductor chip 130, which is a good product, in a wafer WF (S200).

The first and second semiconductor chips 120 and 130 of FIG. 15 may be semiconductor chips determined to be good products (e.g., non-defective products) in the EDS inspection of the operation (S100). In addition, an individualization operation such as a sawing may be performed on the first semiconductor chip 120 before the (S200), so that the first semiconductor chip 120 may be a bare die separated from the wafer.

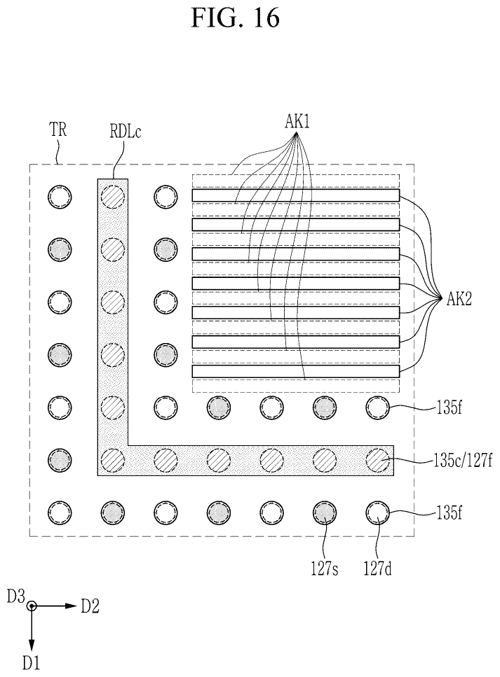

Additionally referring to FIG. 16, by aligning the placement of the first alignment key AK1 of the first semiconductor chip 120 and the second alignment key AK2 of the second semiconductor chip 130 in the test region TR, the first and second semiconductor chips 120 and 130 may be aligned, and the aligned first and the second semiconductor chips 120 and 130 may be bonded to generate the stacking structure SS.

In the alignment of the placement of the first and second alignment keys AK1 and AK2 within the test region TR, each pattern of the second alignment key AK2 may be placed on one side of each pattern of the first alignment key AK1 in a plane perspective. During the alignment process, each pattern of the second alignment key AK2 may be arranged non-overlapping each pattern of the first alignment key AK1 using the third direction D3 as a reference.

According to one or more embodiments, a die bonding device captures and measures an image and absolute position of a first alignment key AK1 and an image and absolute position of a second alignment key AK2, respectively, through a plurality of cameras, and the placement of the first and second alignment keys AK1 and AK2 may be aligned by adjusting the positions of the first and second alignment keys AK1 and AK2.

After the alignment of the first and second alignment keys AK1 and AK2, the plurality of first bonding pads 127 and the plurality of second bonding pads 135 in the test region TR may be directly bonded in a pad-to-pad type by a copper-copper hybrid bonding method. The plurality of first bonding pads 127 and the plurality of second bonding pads 135 may be in direct contact with each other without a bump placement.

Similarly, the plurality of first signal power bonding pads 126 and the plurality of second signal power bonding pads 133 may be directly bonded in a pad-to-pad type by a copper-copper hybrid bonding method. The plurality of first signal power bonding pads 126 and the plurality of second signal power bonding pads 133 may be in direct contact with each other without a bump arrangement. In addition, the first passivation layer 128 and the second passivation layer 136 may be bonded to each other by a high temperature annealing process while being in contact with each other, and together with the copper-copper bonding, may have the strong junction strength as a part of the bonding structure of the stacking structure SS.

According to one or more embodiments, the stacking structure SS may be formed by a thermal compressing bonding of the conductive bump and the underfill member.

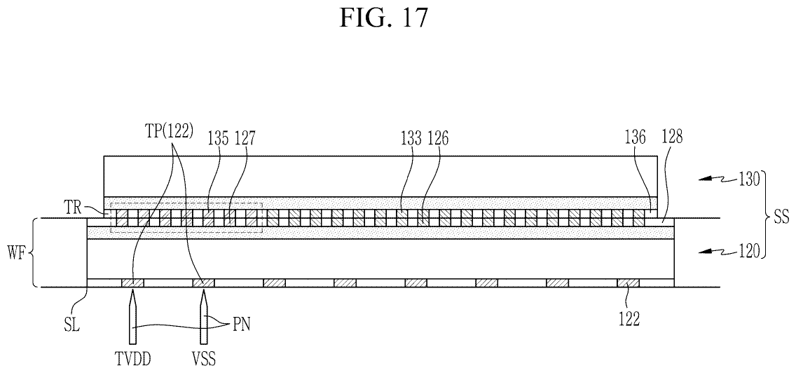

Additionally referring to FIG. 17, a DC test is performed by providing a test signal to the test pad TD among the conductive pads 122 arranged on the rear surface of the second semiconductor chip 130 (S300).

The test signal may include a test voltage TVDD and a ground voltage VSS of a DC type

At this stage, a probe pin PN may be contacted to the test pad TD, and the test voltage TVDD and the ground voltage VSS may be provided to the stacking structure SS through the test pad TD. The test pad TD may be electrically connected to at least some of the plurality of first bonding pads 127.

The alignment of the stacking structure SS is tested by detecting the current corresponding to the test signal (S400).

If the first semiconductor chip 120 and the second semiconductor chip 130 are aligned in the stacking structure SS, a current path for the test signal is not formed within the stacking structure SS so that a current may not be detected at the probe pin PN contacted to the test pad TD.

If the first semiconductor chip 120 and the second semiconductor chip 130 within the stacking structure SS are not aligned, a current path for the test signal may be formed within the stacking structure SS, and the current may be detected at the probe pin PN contacted with the test pad TD.

If no current corresponding to the test signal is detected, the stacking structure SS is determined as a good product (S500).

If no current corresponding to the test signal is detected from the test pad TD of the stacking structure SS, it may be determined that the alignment and junction of the first semiconductor chip 120 and the second semiconductor chip 130 in the stacking structure SS have been performed normally. Based on the determination, the stacking structure SS may be determined as a good quality.

If a current corresponding to the test signal is detected, the stacking structure SS is determined as a defective (S600).

If the current corresponding to the test signal is detected from the test pad TD of the stacking structure SS, it may be determined that the alignment and junction of the first semiconductor chip 120 and the second semiconductor chip 130 in the stacking structure SS are abnormally performed. Based on the determination, the stacking structure SS may be determined as a defective.

The individualization of the stacking structure SS is performed by sawing the wafer WF (S700).

After the testing for the stacking structure SS, the wafer WF including the second semiconductor chip 130 may be cut along the scribe lane SL to produce the individualized stacking structures SS.

The stacking structure SS determined to be a good product is attached to the package substrate 110 (S800).

According to one or more embodiments, the stacking structure SS determined to be a good product may be attached to the package substrate 110 through bump 123. During the attachment process, a thermal compression bonding to the bump 123 and the first underfill member 151 may be performed.

The bump 123 may be disposed on conductive pad 122 disposed on the lower surface of stacking structure SS and may be bonded to the substrate pad 117 disposed on the package substrate 110. In one or more examples, the first underfill member 151 between the stacking structure SS and the package substrate 110 may be interposed between the package substrate 110 and the first semiconductor chip 120.

The manufacturing method of the semiconductor package of the present disclosure may utilize the alignment key of the test region in the inter-chip bonding operation and utilize the pad within the test region in the alignment test operation. The manufacturing method of the semiconductor package of the present disclosure may efficiently perform the image inspection, which requires a relatively long period of time, by utilizing the alignment keys and the pads of the test region together, and improve the efficiency of the entire process.

The manufacturing method of the semiconductor package of the present disclosure may facilitate the alignment testing by arranging the bonding pads in the test region without arranging a separate dedicated circuit in the stacking structure SS.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a first semiconductor chip comprising:
a first substrate,
a first wiring layer on a first surface of the first substrate,
a plurality of first dummy pads electrically connected to each other by a redistribution layer disposed between the first wiring layer and a first passivation layer, and
a plurality of second dummy pads disposed adjacent to the plurality of first dummy pads on the first wiring layer, wherein each second dummy pad of the plurality of second dummy pads is floated; and
a second semiconductor chip comprising:
a second substrate,
a second wiring layer on the second substrate and opposite to the first surface of the first substrate,
a plurality of third dummy pads having at least a portion that overlaps the plurality of first dummy pads on the second wiring layer, and
a plurality of power pads arranged adjacent to the plurality of third dummy pads and configured to provide a test voltage.

2. The semiconductor package of claim 1, wherein:
the plurality of second dummy pads are electrically isolated from a first wiring structure in the first wiring layer, and
the plurality of third dummy pads are electrically isolated from a second wiring structure within the second wiring layer.

3. The semiconductor package of claim 2, wherein:
the plurality of first dummy pads and the redistribution layer are electrically isolated from the first wiring structure.

4. The semiconductor package of claim 1, wherein:
the plurality of power pads comprise a plurality of first power pads configured to provide the test voltage and a plurality of second power pads configured to provide a ground voltage.

5. The semiconductor package of claim 4, wherein:
one or more of the plurality of first power pads and one or more of the plurality of second power pads are alternately arranged along a first direction on the first surface of the first substrate.

6. The semiconductor package of claim 1, wherein:
the plurality of power pads are electrically connected to the second wiring structure within the second wiring layer.

7. The semiconductor package of claim 6, wherein:
the second substrate comprises a second surface facing the first surface of the first substrate and a third surface opposite the second surface,
the second semiconductor chip further comprises a test pad on the third surface and electrically connected to the plurality of power pads.

8. The semiconductor package of claim 7, further comprising:
a substrate facing the third surface,
wherein the second semiconductor chip and the substrate are bonded via a bump.

9. The semiconductor package of claim 1, wherein:
the plurality of first dummy pads are arranged in an L shape on the first surface,
the redistribution layer is arranged in an L shape between the first surface and the plurality of first dummy pads, and
the plurality of first dummy pads are in contact with the redistribution layer.

10. The semiconductor package of claim 1, wherein:
the plurality of first dummy pads are arranged in a bar shape including at least two columns on the first surface,
the redistribution layer is arranged in a bar shape between the first surface and the plurality of first dummy pads, and
the plurality of first dummy pads are in contact with the redistribution layer.

11. The semiconductor package of claim 1, wherein:
the plurality of first dummy pads and the plurality of third dummy pads are electrically connected through a conductive bump.

12. The semiconductor package of claim 1, wherein:
one or more of the plurality of first dummy pads and one or more of the plurality of third dummy pads are in contact with each other.

13. The semiconductor package of claim 12, wherein:
the first semiconductor chip further comprises the first passivation layer that does not cover one or more of the plurality of first dummy pads and does not cover one or more of the plurality of second dummy pads,
the second semiconductor chip further comprises a second passivation layer that does not cover one or more of the plurality of third dummy pads and one or more of the plurality of power pads, and
at least a portion of the first passivation layer and at least a portion of the second passivation layer are in contact with each other.

14. A semiconductor package comprising
a first semiconductor chip comprising:
a first normal region overlapping in a plane a center of a first surface of a first substrate,
a plurality of signal power pads,
a first test region overlapping edges of the first surface,
a plurality of first dummy pads electrically connected to each other,
a plurality of second dummy pads positioned adjacent to the plurality of first dummy pads, wherein each second dummy pad of the plurality of second dummy pads is floated, and
a first alignment key positioned adjacent to the plurality of first dummy pads and the plurality of second dummy pads; and
a second semiconductor chip comprising:
a second test region overlapping the first test region with at least a portion on a second surface of a second substrate facing the first surface of the first substrate,
a plurality of power pads having at least a part that overlaps the plurality of second dummy pads and configured to provide a test voltage, and
a second alignment key corresponding to the first alignment key.

15. The semiconductor package of claim 14, wherein:
the second test region further comprises a plurality of third dummy pads disposed overlapping the plurality of first dummy pads with at least a part on the second surface, wherein each third dummy pad from the plurality of third dummy pads is floated.

16. The semiconductor package of claim 14, further comprising:
a third semiconductor chip that does not overlap the first semiconductor chip on the second surface of the second substrate,
wherein the third semiconductor chip further comprises a second normal region corresponding to the first normal region and a third test region corresponding to the first test region.

17. The semiconductor package of claim 16, wherein:
the second semiconductor chip further comprises a fourth test region having at least a part that overlaps the third test region.

18. A manufacturing method of a semiconductor package comprising:
bonding a first semiconductor chip onto a first surface of a second semiconductor chip at a wafer level using an alignment key;
providing a test signal to the second semiconductor chip using a test pad arranged on a second surface of the second semiconductor chip opposite to the first surface of the second semiconductor chip;
testing an alignment of a stacking structure including the first semiconductor chip and the second semiconductor chip by detecting a current corresponding to the test signal at the test pad; and
sawing a wafer including the second semiconductor chip.

19. The manufacturing method of the semiconductor package of claim 18, wherein:
the test signal includes a test voltage and a ground voltage,
providing the test signal further comprises providing the test voltage and the ground voltage to the test pad through a probe pin, and
testing the alignment further comprises detecting the current corresponding to the test signal through the probe pin.

20. The manufacturing method of the semiconductor package of claim 19, further comprising:
determining the stacking structure as a non-defective product in response to the current not being detected in the testing of the alignment.
